(19) United States
(12) Patent Application Publication
(10) Pub. No.: US 2003/0204803 A1
(43) Pub. Date: Oct. 30, 2003

(54) Method and apparatus for improving observability of signals internal to VLSI chips

(76) Inventors: Michael C. Sedmak, Windsor, CO (US); Warren Kurt Howlett, Windsor, CO (US); Edward Chang, Fort Collins, CO (US)

Correspondence Address: HEWLETT-PACKARD COMPANY, Intellectual Property Adminstration, P.O. Box 272400, Fort Collins, CO, 80527-2400, US

(21) Appl. No.: 10/133,092

(22) Filed: Apr. 26, 2002

(51) Int. Cl. G01R 31/28; G06F 12/00

(52) U.S. Cl. 714/733; 711/104; 711/167

(57) ABSTRACT

An embodiment of the invention provides an improved circuit and method for capturing and observing internal signals on an integrated circuit. Internal signals are routed to a multiplexer that either selects normal-operation signals or debug signals. A counter creates addresses where the debug signals are be stored in an on-chip RAM. A second multiplexer selects either normal-operation addresses or addresses created by the counter. The output of the second multiplexer provides addresses for the on-chip RAM. After debug signals are stored in the on-chip RAM, they may, at a later time, be read from the RAM to a BIST engine.

### FIELD OF THE INVENTION

This invention relates generally to electronic circuits. More particularly, this invention relates to integrated electronic circuits and test methodologies.

### BACKGROUND OF THE INVENTION

Very Large Scale Integrated (VLSI) chips may contain millions of transistors and electrical connections. Because VLSI chips may be so complex, a great deal of testing may be required to verify that a particular chip is fully functional. Observation of signals internal to modern chip designs can be extremely difficult due to the small size of the features on the chip. Some features on modern chips may be as small as 1 millionth of a centimeter. These small features can make it very difficult to “probe” an actual electrical node on a VLSI chip. Methods used to probe internal nodes on a VLSI chip include micro probing and e-beam probing. Either of these methods is time consuming and may require various layers of the chip to be physically removed.

Another method used to observe the value or state of an electrical node is to include “scan chain” circuitry along with the normal circuits. A scan chain may include many memory elements that can store electrical values of many nodes of the normal circuitry. These stored values may then be “clocked” from one scan chain memory element to another and then to one or more output pads on the chip. The values presented on the output pads may then be driven to an external tester that may then evaluate the stored electrical values. In order to scan the electrical values captured in the scan chain, the normal operation of the chip must be stopped. Starting and stopping the normal operation of the chip and scanning the state of many electrical nodes may take a great deal of time.

Another method that may be used to test and debug the functionality of a VLSI chip is to use “broadside vectors.” A test program evaluates the function of the VLSI chip and from that evaluation, the program produces a set of signals or “vectors” that may be applied to the VLSI chip. For each set of signals the test program produces to be applied to the VLSI chip, there is another set of signals or vectors that should appear on the outputs of the VLSI chip. An external tester measures the set of outputs that appear on the VLSI chip and determines if these outputs match the values predicted by the test program. By generating many “broadside” vectors, part of the functionality of the VLSI chip may be determined. This method may require a great deal of computer time to create the vectors as well as a great deal of time to actually apply the vectors to the chip.

There is a need in the art to be able to observe the behavior of critical electrical signals on a VLSI chip on a cycle-by-cycle basis without interrupting the normal operation of the chip.

This invention allows a large number of critical signals, internal to a VLSI chip, to be stored in an internal memory array. The state of a specific group of signals may be stored in the internal memory array on a cycle-by-cycle basis without interrupting the normal operation of the VLSI chip. After a group of signals are stored in the internal memory array, a BIST (Built In Self TEST) engine, also internal to the VLSI chip, reads the signals from the RAM and evaluates the signals. The amount of test data that may be stored in the internal memory array is only limited by the size of the internal memory array.

In addition to enabling signals to be observed for many cycles without interrupting the normal operation of the chip, the invention does not require an additional internal memory array to store test data. A memory array that is used in normal operation may be used to store test data. For example, a TAG RAM normally used to identify whether a word in a cache corresponds to a requested word, may be used to store test data instead. Because an additional memory array is not needed for storing test data, the amount of circuitry need for testing a VLSI chip may be reduced.

### SUMMARY OF THE INVENTION

An embodiment of the invention provides an improved circuit and method for capturing and observing internal signals on an integrated circuit. Internal signals are routed to a multiplexer that either selects normal-operation signals or debug signals. A counter creates addresses where the selected signals may be stored in an on-chip RAM. A second multiplexer selects either normal-operation addresses or addresses created by a counter. The output of the second multiplexer provides addresses for the on-chip RAM. After selected signals are stored in the on-chip RAM, they may, at a later time, be read and evaluated by a BIST engine.

Other aspects and advantages of the present invention will become apparent from the following detailed description, taken in conjunction with the accompanying drawing, illustrating by way of example the principles of the invention.

### BRIEF DESCRIPTION OF THE DRAWINGS

FIG. 1 is a schematic drawing of a circuit used to capture and observe the values of internal nodes on a VLSI chip.

### DETAILED DESCRIPTION OF THE PREFERRED EMBODIMENT

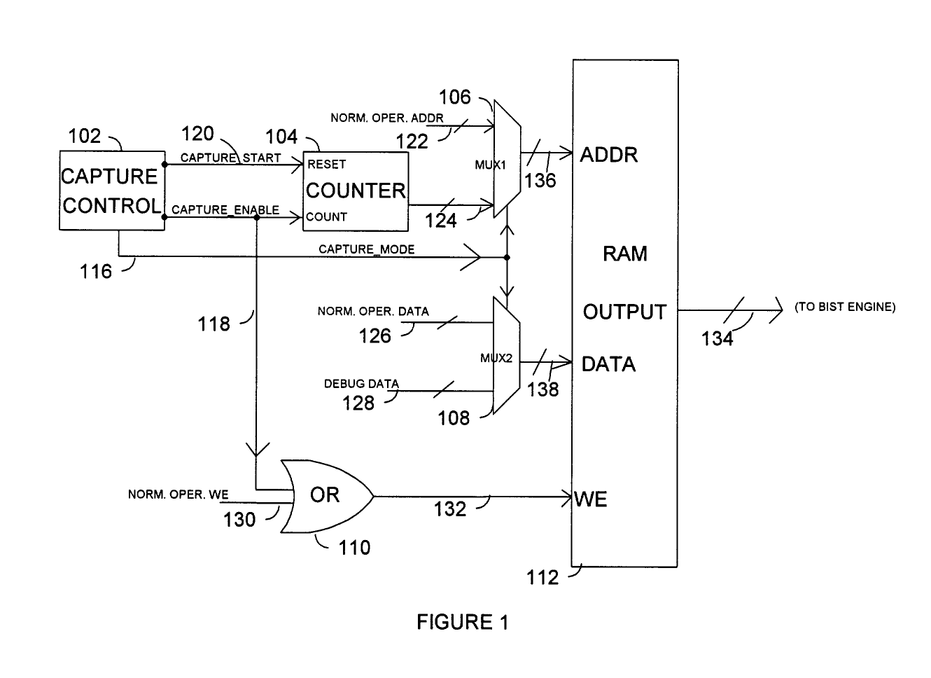

FIG. 1 is a schematic drawing of an example of a circuit used to capture and observe the values of internal nodes on a VLSI chip. An example of the invention includes a RAM array, 112, a counter, 104, a capture control module, 102, two multiplexers, 106 and 108, and an OR function, 110.

The RAM array has an address port, addr, 136, a write enable port, we, 132, a data port, data, 138, and an output port, 134. The RAM stores the data presented at its data port, data, 138, at the address presented at its address port, addr, 136, if the port, we, 132 is high. If the port, we, 132, is not high, data presented at the RAM's data port, data, 138, is not stored. Output data, 134, is read by a BIST engine.

The counter has two inputs, reset, 120, and count, 118. The counter output, 124, outputs a binary address to an input of MUX1, 106. The reset input, 120, of the counter resets the counter output, 124, to zero. The count input, 118, of the counter, causes the counter output, 124, to increment at a predetermined interval, for example one, two or four.

The capture control module generates the three control signals, capture_start, 120, capture_enable, 118, and capture_mode, 116.

MUX1, 106, selects either the output, 124 of the counter or the normal operation address, 122 to be input to the input address port, 136, of the RAM, 112. The signal capture_mode, 116, from the capture control module, 102, determines which input of MUX1, 106, is selected.

MUX2, 108, selects either the debug data, 128 or the normal operation data, 126 to be input to the data port, 138, of the RAM, 112. The signal capture_mode, 116, from the capture control module, 102, determines which input of MUX2, 108, is selected.

OR, 110, has two inputs, capture_enable, 118 and norm. oper. we, 130. Either of these signals may enable the RAM, 112 to accept data. The output, 132, of OR, 110 drives port we of the RAM, 112.

In normal operation, capture_mode, 116 is low. As a result, norm. oper. addr., 122 is selected by MUX1, 106 and applied to the address port, addr., 136, of RAM, 112. In addition, norm. oper. data, 126 is selected by MUX2, 108 and applied to the data port, data, 138, of RAM, 112. Also, when the circuit is in normal operation, the signals capture_start, 120, and capture enable, 118 are low. When the circuit is in this state, normal operation, the RAM is used as it would be under normal chip operation. For example, if the RAM is normally used as TAG RAM, it would be used as a TAG RAM.

When the capture control module, 102, determines debug data should be stored into the RAM, 112, the capture control module, 102, puts a pulse on the capture_start node, 120, followed immediately by driving capture_enable, 118 to a logical “one.” This sequence causes the counter, 104 to reset to zero and then continue counting. The counter, 104 may be incremented at a predetermined interval, for example one, two, or four. The debug data, 128 is stored into the RAM, 112, starting at address zero, 124, and continuing until capture_enable, 118, is driven low by capture control, 102. When capture_enable, 118, goes low, the counter, 104, stops counting, thereby marking the end of the trace. The output data, 134, may be read by a BIST engine.

If the capture continues long enough that the RAM, 112, becomes full, the address, 124, wraps around to zero and continues counting. A “sticky” bit in the counter, 104, gets set and remains set at the rollover. This sticky bit is used to determine the start of the trace. If the sticky bit is clear, then address zero is the trace starting point, otherwise, it's the counter value plus 1. The sticky bit may be read by the BIST engine.

When the cache size setting only uses part of the RAM, 112, both debug data, 128 and norm. oper. data, 126 may be stored in RAM, 112. In cases where the cache size setting uses all the memory in RAM, debug data, 128, may not be captured. This invention makes use of RAM memory that would otherwise be unused. No additional RAM memory is added for the sole purpose of capturing debug data.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) A method for capturing and observing a state of internal signals on an integrated circuit comprising:
a) electrically connecting said internal signals to a first multiplexer on said integrated circuit;
b) selecting inputs of said first multiplexer that allow said internal signals to be clocked into an internal RAM on said integrated circuit;
c) generating addresses where said internal signals are stored in said internal RAM;
d) selecting inputs of a second multiplexer that allow said addresses to be clocked into said internal RAM;
d) storing said internal signals in said RAM;
e) reading said internal signals from said RAM to an internal BIST engine.

2) The method as in claim 1 wherein said addresses are generated by an internal counter.

3) The method as in claim 1 wherein said first multiplexer and said second multiplexer are controlled by an on-chip state-machine.

4) The method as in claim 1 wherein said internal RAM is a SRAM.

5) The method as in claim 1 wherein said internal RAM is a DRAM.

6) The method as in claim 2 wherein said counter is controlled by an on-chip state-machine.

7) A circuit for capturing and observing a state of internal signals on an integrated circuit comprising:
an internal RAM, said RAM having data, address, and control inputs and data outputs;
a first multiplexer, said first multiplexer having at least two sets of inputs, at least one select input, and at least one set of outputs;
a second multiplexer, said second multiplexer having at least two sets of inputs, at least one select input, and at least one set of outputs;
an OR function, said OR function having at least two inputs and at least one output;
a counter, said counter having at least two inputs and at least one set of outputs;
a controller, said controller having at least one input and at least capture-enable, capture-mode and capture-start output bits;
wherein said capture-enable output bit is electrically connected to a first input of said counter and to an first input of said OR function;
wherein said capture-mode output bit is electrically connected to a select input of said first multiplexer and to a select input of said second multiplexer;
wherein said capture-start output bit is electrically connected to a second input of said controller;
wherein a set of outputs from said controller is electrically connected to a first set of inputs of said first multiplexer;
wherein normal-operation address bits are electrically connected to a second set of inputs of said first multiplexer;
wherein a first set of outputs from said first multiplexer is electrically connected to said address inputs of said RAM;
wherein a normal-operation write-enable bit is connected to a second input of said OR function and said output of said OR function is connected to a first control input of said RAM;
wherein said internal signals are electrically connected to a second set of inputs of said second multiplexer and a first set of outputs from said second multiplexer is electrically connected to said set of data inputs to said RAM;
wherein said data outputs of said RAM are electrically connected to a BIST engine located on said integrated circuit.

8) The circuit as in claim 7 wherein said RAM is a DRAM.

9) The circuit as in claim 7 wherein said RAM is an SRAM.

10) The circuit as in claim 7 wherein all functions are implemented using dynamic CMOS.

11) The circuit as in claim 7 wherein all functions are implemented using static CMOS.

12) The circuit as in claim 7 wherein said integrated circuit is a microprocessor.

13) The circuit as in claim 7 wherein said integrated circuit is a DRAM.

14) The circuit as in claim 7 wherein said integrated circuit is a SRAM.

15) The circuit as in claim 7 wherein said integrated circuit is an application specific integrated circuit.
